(19) United States
(12) Patent Application Publication
(10) Pub. No.: US 2026/0012189 A1
(43) Pub. Date: Jan. 8, 2026

(54) Feed-Forward of Low Pass Signal Into Sigma-Delta Loop

(71) Applicant: SiliconIntervention Inc., Kelowna (CA)

(72) Inventor: A. Martin Mallinson, Kelowna (CA)

(21) Appl. No.: 18/764,043

(22) Filed: Jul. 3, 2024

Related U.S. Application Data
(60) Provisional application No. 63/534,482, filed on Aug. 24, 2023.

(51) Int. Cl. H03M 3/00

(52) U.S. Cl. CPC H03M 3/344; H03M 3/424

(57) ABSTRACT

An apparatus for improving the noise performance of a ΣΔ modulator functioning as an ADC. The performance of a ΣΔ modulator of the known art is significantly improved upon if a low pass version of the comparator output is added, preferably with gain, to the comparator output itself, and the sum fed to the loop filter. This may be achieved by adding components, a low pass filter and a gain element, into the loop of the ΣΔ modulator after the comparator and prior to the loop filter. If the additional components form a filter over the band of interest, then the result is a much improved noise performance in the band of interest. Although in general the band of interest will be a low pass band the present approach is not restricted to a ΣΔ modulator used for low frequencies, but rather also applies to band pass ΣΔ modulators.

This application claims priority from Provisional Application No. 63/534,482 filed Aug. 24, 2023, which is incorporated by reference herein in its entirety.

### FIELD OF THE INVENTION

The present invention relates generally to sigma-delta modulators, and more particularly to sigma-delta modulators with improved noise performance.

### BACKGROUND OF THE INVENTION

Quantized feedback may be used in control loops to perform analog to digital conversion. Analog to digital converters (ADCs) with such features are often known as sigma-delta (ΣΔ) converters, or ΣΔ modulators, the modulator term referring to an output digital data stream having a certain symbol pattern, or modulation, imposed upon it by the control loop. The terms ΣΔ modulator and noise shaping control loop are often used interchangeably in the art, although the latter is more descriptive. Circuit designers often like to use such ΣΔ modulators as in many cases they may be simpler to design and cheaper to make than other types of ADCs.

In such a noise shaping control loop, a continuous analog signal is applied at the input, and a digital pattern representative of this signal emerges from the output. The digital signal is created by one or more quantization elements in the control loop, for example, by non-linear elements in the loop such as flip-flops or comparators that have a discrete set of non-continuous output values for any given continuous input quantity.

The ΣΔ modulation works by constraining a feedback parameter to one of a set of at least two specific values, and a control loop of arbitrary order ensures that the average feedback value equals the input. Instantaneous deviations from the ideal continuous feedback necessarily introduced by quantization elements represent noise, and a sophisticated, possibly high order, control loop can suppress or “shape” this noise. To “shape” the noise means to filter it, generally to make it not appear in certain frequency bands. The loop therefore operates to suppress this noise in certain frequency bands of interest, often at the expense of increased noise in bands that are not relevant to the application. Hence ΣΔ modulators are sometimes also referred to a “noise shaping loops.”

One of skill in the art will appreciate that designing the quantizer such that a larger set of output possibilities are available increases the mathematical number of information “bits” in the quantizer and reduces the noise in the ADC. It will also be appreciated that another way of improving the output of such an ADC is to increase the rate at which the input signal is sampled. This requires increasing the speed of operation of the quantizer, and thus the clock speed. However, as is known in the art, both increasing the set of output values of the quantizer beyond a certain point and increasing its clock speed present other problems that reduce the advantages that ΣΔ modulators may have over other ADCs.

For these reasons, a simple and inexpensive way of improving the noise performance of ΣΔ modulators functioning as ADCs may be useful.

### SUMMARY OF THE INVENTION

Described herein is an apparatus for improving the noise performance of a ΣΔ modulator functioning as an ADC.

One embodiment discloses an apparatus, comprising: a comparator configured to receive an input signal and a feedback signal, and to output an error signal that is a difference between the input signal and the feedback signal; a first filter configured to receive as an input the error signal and output a filtered error signal; an amplifier configured to receive the first filtered error signal and output an amplified filtered error signal; an adder configured to receive the error signal and the amplified filtered error signal and output a total error signal that is a sum of the error signal and the amplified filtered error signal; a second filter configured to receive the total error signal and output a filtered total error signal; and a quantizer configured to receive as an input the filtered total error signal and to output as the feedback signal a quantized value that is based upon a value of the filtered total error signal upon receipt of a clock signal.

Another embodiment discloses a method of processing an input signal, comprising: comparing the input signal and a feedback signal to generate an error signal that is a difference between the input signal and the feedback signal; filtering the error signal to generate a filtered error signal; amplifying the first filtered error signal to generate an amplified filtered error signal; adding the error signal and the amplified filtered error signal to generate a total error signal that is a sum of the error signal and the amplified filtered error signal; filtering the total error signal to generate a filtered total error signal; and quantizing the filtered total error signal to generate the feedback signal based upon a value of the filtered total error signal.

### BRIEF DESCRIPTION OF THE DRAWINGS

FIG. 1 is a block diagram of a ΣΔ modulator with a control loop functioning as a simple ADC as is known in the prior art.

FIG. 2 is a block diagram of a ΣΔ modulator with a control loop functioning as a simple ADC according to the present approach.

FIG. 3 is a graph showing the audio performance of a conventional ΣΔ modulator constructed according to the prior art.

FIG. 4 is a graph showing the audio performance of a ΣΔ modulator constructed according to the present approach.

FIG. 5 is a flowchart of a method of performing the function of a ΣΔ modulator according to the present approach.

### DETAILED DESCRIPTION OF THE INVENTION

Described herein is a method and apparatus for improving the noise performance of a ΣΔ modulator functioning as an ADC. The present approach seeks to improve upon the noise performance of prior art ΣΔ modulators.

The performance of a ΣΔ modulator of the known art is significantly improved upon if a low pass version of the comparator output is added, preferably with gain, to the comparator output itself, and the sum fed to the loop filter. This may be achieved by adding components, i.e., a low pass filter and a gain element, into the loop of the ΣΔ modulator after the comparator and prior to the loop filter. If the additional components form a low pass filter, or more specifically form a filter over the band of interest, then the result is a much improved noise performance in the band of interest.

The present approach is not restricted to a ΣΔ modulator used for low frequencies, but rather also applies to band pass ΣΔ modulators; thus, the discussion herein uses “band of interest” to ensure that both cases are covered, although in general the band of interest will be a low pass band.

A ΣΔ modulator is characterized by a discrete set of output quantities expressed over as few as one bit, with a signal imposed upon the discrete outputs. ΣΔ modulators are sometimes called “noise-shaping” devices because the output sequence of discrete quantities may be thought of as having a noise added to the signal. The noise in this analysis is the quantity that must be added to the analog quantity to cause the output to occupy one of the discrete levels. (ΣΔ modulators are sometimes called delta-sigma (ΔΣ) modulators; in some places they may also be called delta (Δ) modulators, although in many places, such as the United States, a delta modulator is considered to have a somewhat different function.)

For example, a single bit ΣΔ modulator accepts a nominally continuous input that is within the range of −1 to 1 and outputs a quantized signal of two states that may be represented as either −1 or 1. The number of occurrences of −1 or 1 is such that the average of the outputs represents the value of the input signal. In this example, if the input signal is 0 then the output is:

$$- 1 \qquad 1 \qquad - 1 \qquad 1 \qquad - 1 \qquad 1$$

It will be seen that this is a sequence of quantized values having an average value equal to the input signal, i.e., 0. However, since there is no 0 output, “noise” of 1 or −1 is added to the input to produce each output value.

This “noise-shaping function” of a ΣΔ modulator may also be seen in another example. If the single bit ΣΔ modulator described above is used to encode an input of 0.5 the output sequence might be:

$$- 1 \qquad 1 \qquad 1 \qquad 1 \qquad - 1 \qquad 1 \qquad 1 \qquad 1 \qquad - 1 \qquad 1 \qquad 1 \qquad 1 \qquad etc .$$

It will be seen that this sequence has an average value of 0.5, i.e., ¾ of the range from −1 to 1, which is 0.5 and equal to the input. Again, “noise” has been added to this input in sequence, i.e., values of −1.5, 0.5, 0.5, 0.5 etc. are added in sequence to the input value of 0.5 to get the discrete output sequence from the ΣΔ modulator.

Considering a ΣΔ modulator in this way, i.e., as a device that adds noise to a continuous signal in such a way as to generate a sequence of discrete outputs, the frequency domain characteristics of the noise may be analyzed. Such analysis is known in the art.

Those of skill in the art generally refer to the “order” of the noise shape in the frequency domain; the order is the order of the filter in the loop, and a higher order filter will result in more suppression of the error in the output signal. First order ΣΔ modulators, or “first order noise shapers,” have a noise that rises 6 decibels (db) per octave (or equivalently 20 db per decade or order of magnitude). Second order noise shapers have regions of noise that rises at 12 db per octave, and so forth. Some forms of ΣΔ modulator have zeros in the noise, i.e., they have a spectrum of noise that nominally goes to zero at a specific frequency.

In addition to the quantization in amplitude required by the discrete output amplitudes of the ΣΔ modulator, there is also an implied quantization in time. The elements of the quantized output are changing at discrete and generally predictable times. In the prior art, as in typical digital systems the quantization in time of the ΣΔ modulator is achieved by the use of a clock signal, a digital event at a specific time, at which time the ΣΔ modulator makes the transitions between the discrete output levels.

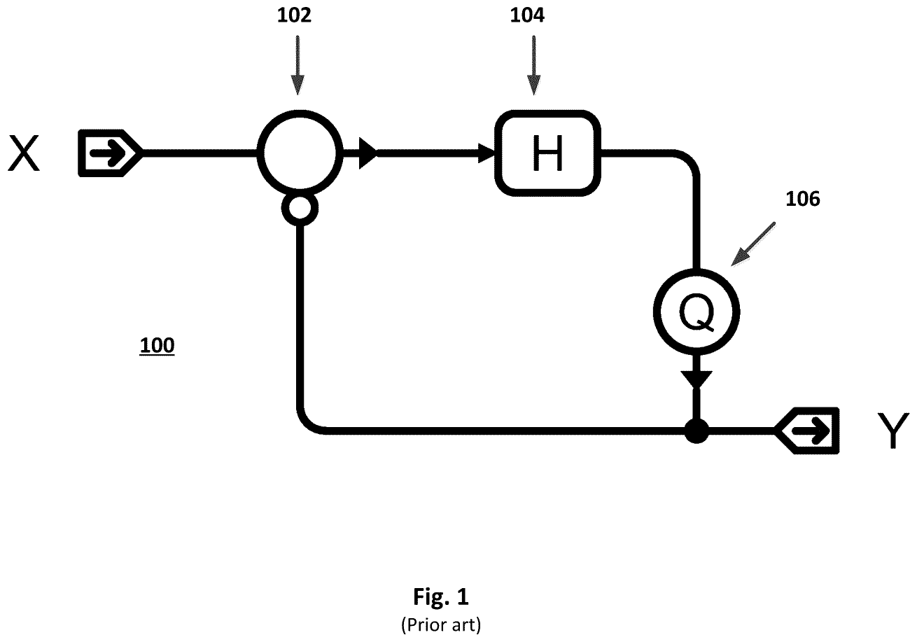

FIG. 1 is a diagram of a ΣΔ modulator 100 of the prior art. A comparator 102 (sometimes called a differencing element) compares the input signal X to the feedback signal Y from a quantizer 106; the output of comparator 102, which is an error signal, is thus equal to the input signal X minus the output signal Y. This difference is the input to a loop filter 104 that operates on the output of comparator 102 and generates a filtered error signal that drives the input to quantizer 106. As is common in the art, for discussion below, filter 104 is considered to have a function “H” and quantizer 106 is considered to have a function “Q”.

The quantizer 106 accepts a nominally continuous filtered error signal from filter 104 and quantizes that signal, i.e., forces that signal into discrete amplitude values at discrete times when it is ‘clocked’ by a digital clock such that the quantizer level outputs occur on each clock edge. Quantizer 106 may, for example, be a D-type flip flop (DFF). In the simplest case, as above, the quantizer may output −1 or 1 (i.e., a one-bit encoding) or, in the more general case, one of a set of discrete integer values, for example one of the integers between −63 and +63 inclusive.

Every clock edge provided by a clock signal will cause quantizer 106 to update the output Y, in the case of a one-bit encoding to a high level if the input to quantizer 106 is high and to a low level if the input to quantizer 106 is low, or to other values in the case of a multi-bit encoding. Since filter 104 is generally an integrator with a 1/s characteristic as part of the transfer function, the average value of the output Y of quantizer 104 thus must equal input signal X.

The operation of a ΣΔ modulator such as ΣΔ modulator 100 may be considered in a way that may be described as “semi-mathematical,” using equations such as those below that represent the functionality of a ΣΔ modulator in a way that is often used by those in the art, although they do not precisely describe all the intricacies of such operation.

The analysis of the operation of ΣΔ modulator 100 proceeds as follows. As above, filter 104 is considered to have a function “H” and quantizer 106 is considered to have a function “Q”. The connectivity of ΣΔ modulator 100 thus results in:

$$H * ( X - Y ) + Q = Y , or \qquad ( Equation 1 )$$

$$Y = X * H / ( 1 + H ) + Q / ( 1 + H ) \qquad ( Equation 2 )$$

Equation 2 has two parts, a first part which includes the input signal X, and a second part which does not include the input signal but rather the function Q of the quantizer.

The first part of Equation 2 is the input signal X times a value H/(1+H) which depends upon the function H of the filter 104. The value H/(1+H) is commonly referred to as the “signal transfer function” (STF) of the ΣΔ modulator. The second part of Equation 2 is the quantizer function, Q times a value 1/(1+H), which again depends upon the function H of the filter 104. The value 1/(1+H) is commonly referred to as the “noise transfer function” (NTF).

Generally, filter 104 is a low pass filter, and, as above and as known in the art, the function H of filter 104 has a 1/s characteristic, i.e., the response of a filter can be expressed by an s-domain transfer function; the variable s is the usual definition of j times w and comes from the Laplace transform and represents complex frequency.

Thus, the function H of filter 104, due to its 1/s characteristic, increases as s gets smaller. As a result, as s, and the frequency, goes to zero H gets very large, so that the signal transfer function, H/(1+H), will go to 1, while the noise transfer function, 1/(1+H), will go to zero. (In some band pass modulators, H will get large at a finite s, rather than as s goes to zero.)

It is this separation of the signal transfer function from the noise transfer function that allows the filter function H to be tailored in a way to reduce the noise of the quantizer, and thus the ΣΔ modulator, to be reduced in the signal band of interest using the present approach.

One of skill in the art will appreciate that the ΣΔ modulator should remain stable. If there is any frequency at which the feedback augments, rather than diminishes, the output of the comparator, the loop at this frequency is unstable, i.e., has unstable positive feedback. Analysis of a loop is well known in the art; Bode's criteria for stability is commonly used and will indicate those frequencies at which the loop has unstable positive feedback and will oscillate (typically high frequencies).

Stability of the ΣΔ modulator is determined by the function H of filter 104. To achieve stability and prevent this oscillation, either the open loop gain is reduced or the phase near the onset of positive feedback is adjusted to ensure that the loop gain is less than unity by the time a phase shift of 180 degrees has been accumulated. It is typical to make the cross-over frequency at which this occurs, known as the unity gain bandwidth (“UGB”), as high as possible. It is well known in the art how to make these changes and ensure stability.

If the loop is stable, the Bode criteria requires that the phase margin, i.e., the degree to which the phase is less than the critical 180 degrees, must be positive. A common rule of thumb is that the phase margin should exceed 65 degrees at the UGB for good time domain response.

These adjustments for stability are employed in the frequency region where the ΣΔ modulator is prone to exhibit oscillation and are at a frequency significantly different from the frequencies in the band of interest. This suggests that a method for incremental improvement of the ΣΔ modulator (i.e., further reduction in the noise) can be applied if it does not interfere with gain or phase near the frequency of instability.

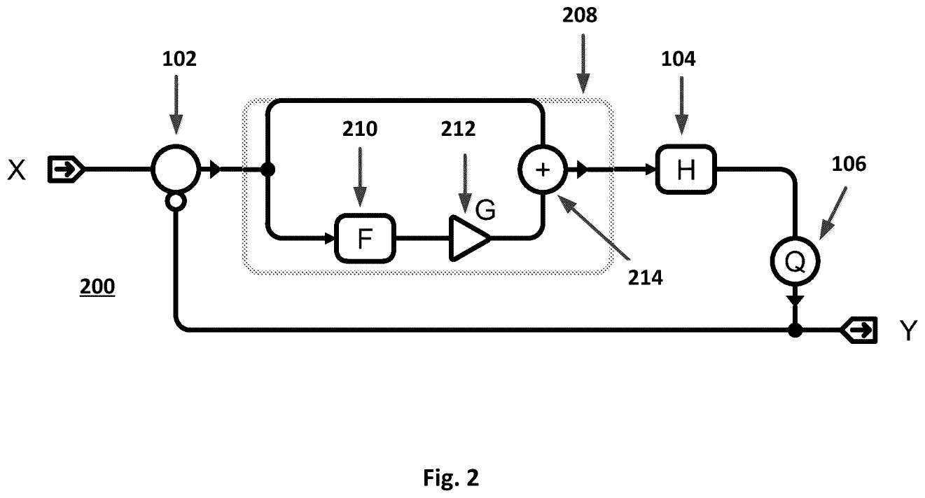

FIG. 2 is a diagram of a ΣΔ modulator 200 according to the present approach. The comparator 102, filter 104 and quantizer 106 are the same as in ΣΔ modulator 100 in FIG. 1 and operate as described above, and the functions H and Q of filter 104 and quantizer 106, respectively, are the same as in FIG. 1.

However, ΣΔ modulator 200 adds circuitry 208 between comparator 102 and filter 104. Circuitry 208 contains a second filter 210 with a function F, an amplifier 212 with a gain G, and an adder 214.

Filter 210 receives the output of comparator 102, as above an error signal that is the difference between the input signal and a feedback signal, and the result is filtered by a filter 210 to produce a filtered error signal. The filtered error signal is then multiplied by amplifier 212, which has a gain G, to produce an amplified filtered error signal. Adder 214 then adds the output of amplifier 212, the amplified filtered error signal, to the error signal from comparator 102 to produce a total error signal, and the total error signal is then filtered by filter 104 to produce a filtered total error signal.

Quantizer 106 then quantizes the filtered total error signal (rather than the error signal from comparator 102 as in FIG. 1) to produce the output, which is also the feedback signal provided to comparator 102.

The effect of circuitry 208 is thus to effectively apply a second filter to the output of comparator 102, which may be represented as 1+F*G. While one could simply represent circuitry 208 as a filter “F-prime” such that F-prime=1+F*G, illustrating the additional components as shown in FIG. 2, including filter 210, amplifier 212 and adder 214, clarifies the fact that the use of these additional components represents an addition to the known art that includes both a new filter and a gain term.

In the present approach, the function F suppresses the signal out of comparator 102 in the signal band of interest. It is typical, but not necessary, that the ΣΔ modulator be designed such that the quantization noise created by quantizer 106 is moved to a high frequency and the signal band of interest is a low frequency.

Thus, in a common audio use of a ΣΔ modulator, the filter F may typically extend over the low frequency audio range of interest. For example, the signal of interest may extend from 20 hertz (“Hz”) to 20 kilohertz (“kHz”) and the quantizer may operate, i.e., be clocked, at 400 kHz.

The mathematical analysis of ΣΔ modulator 200 proceeds as before, but now the filter factor H is replaced by a new filter factor H*(1+F*G):

$$H * ( 1 + F * G ) * ( X - Y ) + Q = Y ; hence \qquad ( Equation 3 )$$

$$Y = X * H * ( 1 + F * G ) / ( 1 + H * ( 1 + F * G ) ) + Q / ( 1 + H * ( 1 + F * G ) ) \qquad ( Equation 4 )$$

It may be seen that mathematically the denominator of each function increases from 1+H to 1+H*(1+F*G). Since the filter factor in the numerator of the signal transfer function also increases from H to H(1+F*G), the signal transfer function is not significantly affected by the change in the filter factor. However, the noise transfer function does not have a filter factor in the numerator, and thus the increase in the denominator will reduce the noise transfer function.

A low pass ΣΔ example is used to explain this. As the function of filter F goes to 0, circuit 200 of FIG. 2 effectively becomes circuit 100 of FIG. 1. Well below the ΣΔ loop bandwidth, for example at 200 kHz, the filter F has rolled-off such that 1+F*G approximates unity (i.e., F*G is very small). For example, F may be a fourth order 20 kHz filter and at 200 kHz has a response of −80 dB which may be neglected. Hence at these high frequencies the loop stability remains as before. However, if the gain G=20 for example, in the band of interest H may be 21× larger, since H→H*(1+F*G)=21*H. The signal transfer function is largely unaffected, but the noise transfer function is much reduced, by a factor of about 21.

It is again desirable that the ΣΔ modulator 200 remain stable. The additional filter 210 is now part of the loop, and thus the function F of filter 210 must be taken into account, since as above the loop filter factor is now H*(1+F*G). One way to ensure loop stability would be to do a rigorous analysis of the loop stability using the new loop filter factor; however, this analysis may be complex.

A simpler way to approach this is to recall that, as above, loop stability depends upon the precise phase as the loop passes though the UGB frequency. If by adding the function F of filter 210 the phase at the UGB point is not altered, the loop will remain stable, i.e., if the effect of filter function F is not present before the UGB frequency is reached. For this to be true, filter 210, a low pass filter, should have no response at the UGB frequency. In other words, the filter function F of filter 210 must roll off long before the filter function H of filter 104 passes through 0 dB so that it does not affect the stability of the loop.

A commonly used rule of thumb is that a 10 kHz first order low pass filter will be 40 db down at, for example, a UGB of 1 megahertz (“MHz”) (20 db per decade), However, if it is desired that the effect of filter function F, which as above vastly improves the noise of the ΣΔ modulator, carry on up to, for example, 40 kHz, filter 210 with filter function F will need to be a higher order filter that lets a 40 kHz signal through but rolls off to, for example, −80 db at 1 MHz. This requires an order O where 25°>10,000 (25 is the ratio of 40 kHz to 1 MHz, 10,000 is 80 dB). A third order filter would yield only 83 dB (253=15,620), so to be sure one would preferably use a fourth order filter. One of skill in the art will be able to select appropriate filters for different frequencies and applications.

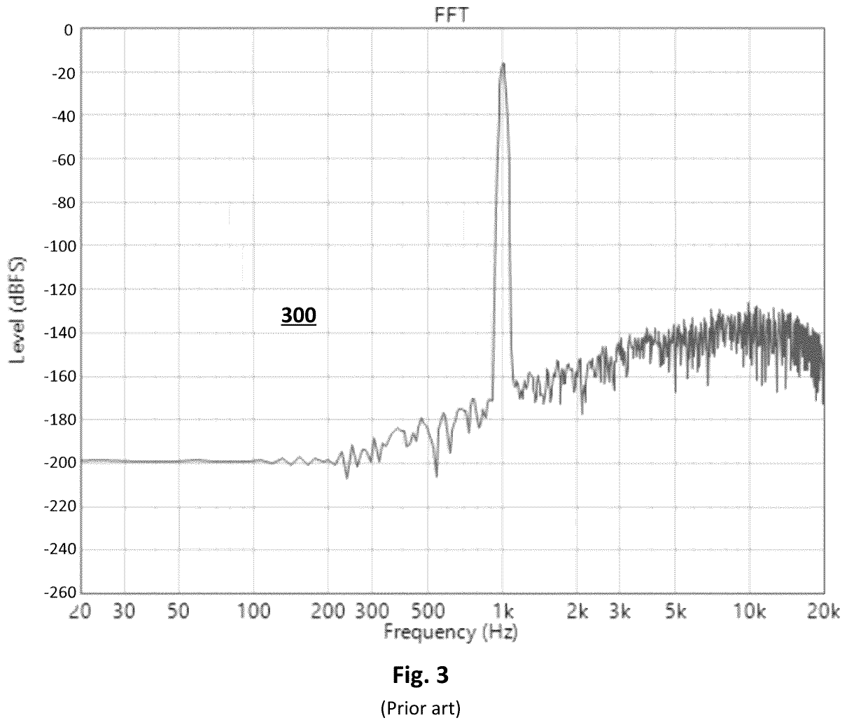

FIG. 3 is a graph 300 of the output of a ΣΔ modulator of the prior art, such as ΣΔ modulator 100, operating on a 1 kilohertz (kHz) signal, such as an audio signal, using a 7-bit quantizer with outputs from −63 to 63, inclusive, clocked at about 400 kHz. As can be seen, the noise gradually increases above about 200 Hz, and is higher at frequencies above the signal at 1 kHz than at frequencies below 1 kHz.

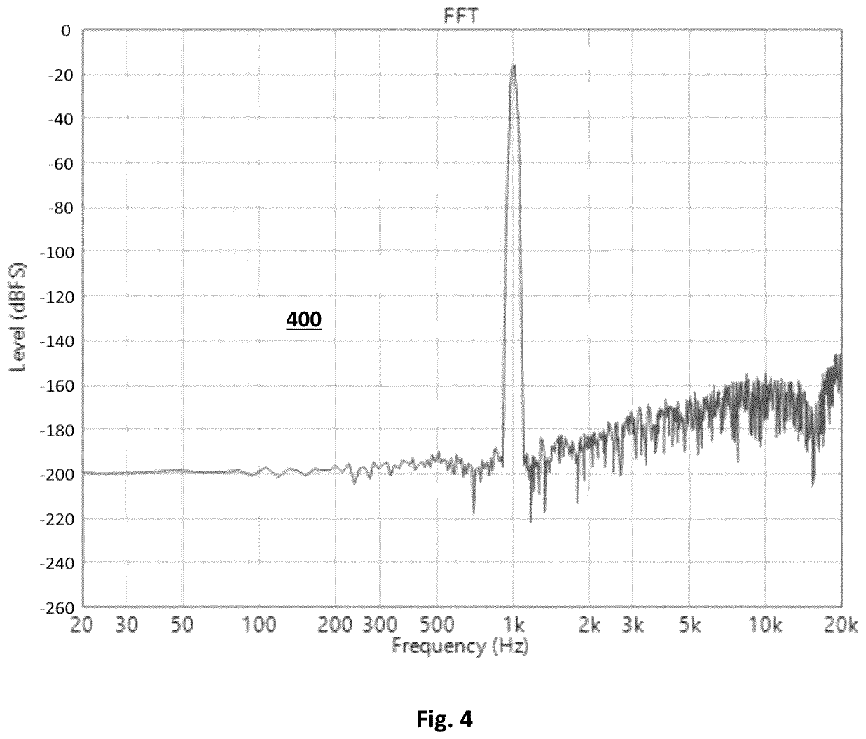

FIG. 4 is a graph 400 of the output of a ΣΔ modulator of the present approach, such as ΣΔ modulator 200, again operating on a 1 kilohertz (kHz) signal and using a 7-bit quantizer with outputs from −63 to 63, inclusive, clocked at about 400 kHz. The filter H is the same as the filter used to produce FIG. 3. The additional filter F is a fourth order filter at 20 kHz, and the gain of the amplifier is 20.

It may be seen that using the present approach has improved noise reduction at frequencies both below and over 1 kHz, with the average weighted performance increasing by about 25 dB, from about 97 dB to 122 dB. All of the stability criteria of the circuit are unchanged; as above, stability depends upon the loop behavior well above the band of interest. The additional components of the ΣΔ modulator affect only the band of interest and deliver a significant improvement.

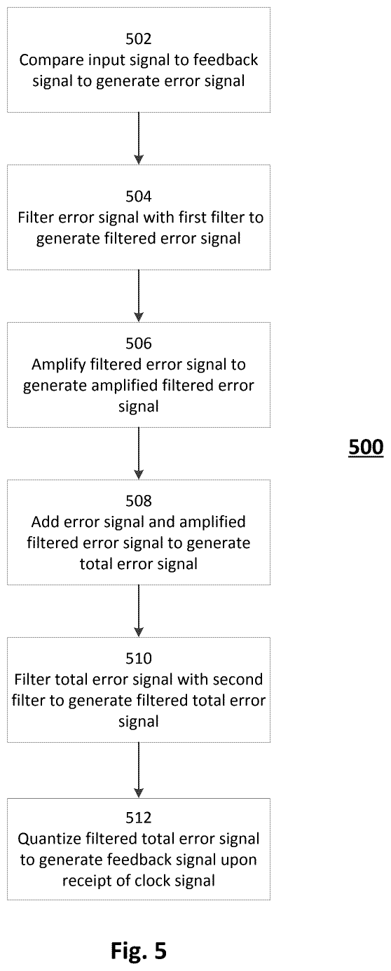

FIG. 5 is a flowchart of a method 500 of performing the function of a ΣΔ modulator according to the present approach. The discussion below refers to hardware components, and specifically to the components of circuit 200 of FIG. 2 above. However, one of skill in the art will appreciate that all of these steps may be performed completely in software as part of a digital signal processor or other processing means.

At step 502, the input signal is compared to a feedback signal by, for example, a comparator such as comparator 102 in circuit 200 of FIG. 2, to generate an error signal.

At step 504, the error signal is filtered by, for example, a first filter, such as filter 210 in circuit 200 of FIG. 2, to generate a filtered error signal.

At step 506, the filtered error signal is amplified by for example, an amplifier, such as amplifier 212 in circuit 200 of FIG. 2, to generate an amplified filtered error signal.

At step 508, the error signal and the amplified filtered error signal are added together by, for example, an adder, such as adder 214 in circuit 200 of FIG. 2, to generate a total error signal.

At step 510, the total error signal is filtered by, for example, a second filter, such as filter 104 in circuit 200 of FIG. 2, to generate a filtered total error signal.

At step 512, the filtered total error signal is quantized by, for example, a quantizer, such as quantizer 104 in circuit 200 of FIG. 2, to generate the feedback signal, which is also the output signal of the ΣΔ modulator.

The disclosed system has been explained above with reference to several embodiments. Other embodiments will be apparent to those skilled in the art in light of this disclosure. Certain aspects of the described method and apparatus may readily be implemented using configurations other than those described in the embodiments above, or in conjunction with elements other than or in addition to those described above. For example, as is well understood by those of skill in the art, various choices will be apparent to those of skill in the art. Further, the illustration and description of certain filters, quantizers, etc., is exemplary; one of skill in the art will be able to select the appropriate types of filters and related elements that are appropriate for a particular application.

These and other variations upon the embodiments are intended to be covered by the present disclosure, which is limited only by the appended claims.

What is claimed is:

1. An apparatus, comprising:
a comparator configured to receive an input signal and a feedback signal, and to output an error signal that is a difference between the input signal and the feedback signal;
a first filter configured to receive as an input the error signal and output a filtered error signal;
an amplifier configured to receive the first filtered error signal and output an amplified filtered error signal;
an adder configured to receive the error signal and the amplified filtered error signal and output a total error signal that is a sum of the error signal and the amplified filtered error signal;
a second filter configured to receive the total error signal and output a filtered total error signal; and
a quantizer configured to receive as an input the filtered total error signal and to output as the feedback signal a quantized value that is based upon a value of the filtered total error signal upon receipt of a clock signal.

2. The apparatus of claim 1 wherein the first filter and the second filter are configured to suppress the error signal in a selected signal band of interest.

3. The apparatus of claim 2 wherein the first filter and the second filter are band-pass filters configured to pass frequencies in the selected signal band of interest.

4. The apparatus of claim 3 wherein the first filter and the second filter are low-pass filters configured to pass frequencies from approximately 20 hertz (Hz) to 20 kilohertz (kHz).

5. The apparatus of claim 4 wherein the quantizer is configured to receive clock signals and generate output signals at a rate of 400 kHz.

6. The apparatus of claim 2 wherein the first filter is of an order higher than a first order filter.

7. The apparatus of claim 6 wherein the first filter is a fourth order filter.

8. The apparatus of claim 1 wherein the amplifier is configured to amplify the filtered error signal by approximately 20 times.

9. The apparatus of claim 1 wherein the quantizer is configured such that each output of the quantizer comprises a plurality of bits.

10. The apparatus of claim 9 wherein each output of the quantizer comprises 7 bits representing values from −63 to 63, inclusive.

11. A method of processing an input signal, comprising:
comparing the input signal and a feedback signal to generate an error signal that is a difference between the input signal and the feedback signal;
filtering the error signal to generate a filtered error signal;
amplifying the first filtered error signal to generate an amplified filtered error signal;
adding the error signal and the amplified filtered error signal to generate a total error signal that is a sum of the error signal and the amplified filtered error signal;
filtering the total error signal to generate a filtered total error signal; and
quantizing the filtered total error signal to generate the feedback signal based upon a value of the filtered total error signal.

12. The method of claim 1 wherein filtering the error signal and filtering the total error signal suppress the error signal in a selected signal band of interest.

13. The method of claim 12 wherein filtering the error signal and filtering the total error signal comprise band-pass filtering that passes frequencies in the selected signal band of interest.

14. The method of claim 13 wherein filtering the error signal and filtering the total error signal comprise low-pass filtering configured to pass frequencies from approximately 20 hertz (Hz) to 20 kilohertz (kHz).

15. The method of claim 14 wherein the filtered total error signal is quantized at a rate of 400 kHz.

16. The method of claim 12 wherein filtering the error signal comprises applying a filter having an order higher than a first order filter.

17. The method of claim 16 wherein filtering the error signal comprises applying a fourth order filter.

18. The method of claim 11 wherein amplifying the filtered error signal to generate an amplified filtered error signal comprises amplifying the filtered error signal by approximately 20 times.

19. The method of claim 11 wherein quantizing the filtered total error signal further comprises quantizing the filtered total error signal to a value comprising a plurality of bits.

20. The method of claim 19 wherein quantizing the filtered total error signal further comprises quantizing the filtered total error signal to a value comprising 7 bits representing values from −63 to 63, inclusive.
